(19) United States
(12) Patent Application Publication
(10) Pub. No.: US 2025/0350278 A1
(43) Pub. Date: Nov. 13, 2025

(54) SYSTEM AND METHOD FOR DRIVING A HYBRID SWITCH

(71) Applicant: SEMICONDUCTOR COMPONENTS INDUSTRIES, LLC, Scottsdale, AZ (US)

(72) Inventors: Aditya Shantaram SAWANT, Munich (DE); Rajani Kumar THIRUKOLURI, Munich (DE)

(73) Assignee: SEMICONDUCTOR COMPONENTS INDUSTRIES, LLC, Scottsdale, AZ (US)

(21) Appl. No.: 18/657,148

(22) Filed: May 7, 2024

(51) Int. Cl. H03K 17/284; H03K 17/10

(52) U.S. Cl. CPC H03K 17/284

(57) ABSTRACT

A switch system includes a hybrid switch and a control circuit. The hybrid switch includes an IGBT and a MOSFET. The control circuit includes an input terminal configured to receive a switch-off command. The control circuit further includes an IGBT drive circuit configured to switch off the IGBT in response to expiration of a first delay period that begins in response to the switch-off command. In addition, the control circuit includes a MOSFET drive circuit configured to increase a gate-to-source voltage of the MOSFET from a first voltage level to a second voltage level in response to the switch-off command, to drive the MOSFET at the second voltage level for a second delay period that begins in response to the switch-off command and is longer than the first delay period, and to switch the MOSFET off in response to the expiration of the second delay period.

### TECHNICAL FIELD

The disclosure relates generally to hybrid switches, and particularly to a control scheme for driving a hybrid switch.

### BACKGROUND

Power electronics may be used to control the conversion and distribution of electric power. For example, switching power converters may be used to create a direct current (“DC”) voltage from an alternating current (“AC”) voltage by switching current through a magnetic element such as an inductor. Conversely, inverters can be used to convert a DC voltage to an AC voltage. In these and other forms of power electronics, power switches may be used to control the conversion and flow of power through the power-conversion system and to the electronic circuitry to be powered by the device.

Hybrid switches may be used as the power switch in power conversion systems to improve conduction losses across a wide range of currents. A hybrid switch may include a high-power metal-oxide semiconductor field effect transistor (“MOSFET”) coupled in parallel with an insulated-gate bipolar transistor (“IGBT”). The forward voltage drop of a power MOSFET is typically linear with current. On the other hand, an IGBT typically has a diode-like forward voltage drop characteristic due to the IGBT's internal junction. Thus, when combined in a hybrid switch, the MOSFET may predominate at low currents, and the IGBT may predominate at higher currents. The hybrid device may thus improve conduction losses across a wide range of currents as compared to a power MOSFET or an IGBT alone. However, the inventors of embodiments of the present disclosure have recognized that hybrid switches may incur higher switching losses than, for example, a power MOSFET alone. Inventors of embodiments of the present disclosure have recognized that such higher switching loss may negatively impact the overall efficiency of the power conversion system. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a schematic diagram of a hybrid switch system in accordance with embodiments of the present disclosure.

FIG. 2 illustrates a timing diagram of waveforms received and generated by a delay generator in accordance with embodiments of the present disclosure.

FIG. 3 illustrates a timing diagram of waveforms for controlling a hybrid switch in accordance with embodiments of the present disclosure.

FIG. 4 illustrates a method for controlling a hybrid switch in accordance with embodiments of the present disclosure.

### DETAILED DESCRIPTION

Details of one or more embodiments are set forth in the description below and the accompanying drawings. Other features will be apparent from the description, drawings, and from the claims.

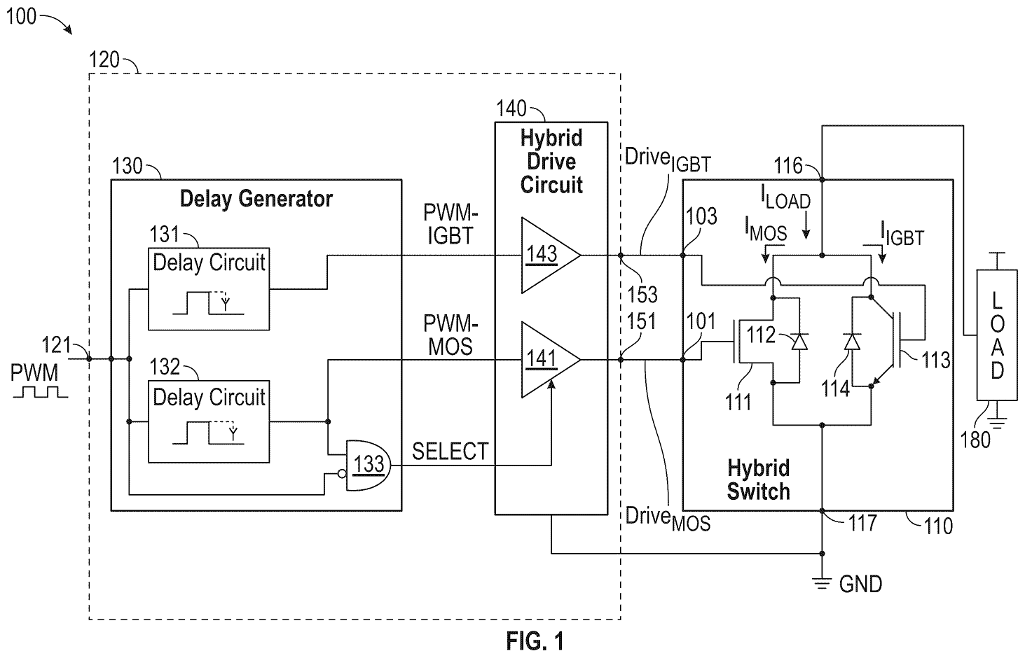

FIG. 1 illustrates a schematic diagram of hybrid switch system 100 in accordance with embodiments of the present disclosure. Hybrid switch system 100 may be implemented in any suitable fashion according to the operation described in the present disclosure. Hybrid switch system 100 may include hybrid switch 110 and control circuit 120. Control circuit 120 may provide control signals for switching on-and-off hybrid switch 110.

As shown in FIG. 1, hybrid switch 110 may be coupled between load 180 and ground GND, and may draw a load current I_{LOAD} from load 180. In some embodiments, load 180 may represent a magnetic element, such as an inductor or a transformer, of a switching power converter. Although FIG. 1 illustrates an example embodiment of hybrid switch 110 serving as a low-side switch coupled between load 180 and ground GND, hybrid switch 110 may also serve as a high-side switch coupled, for example, between a high-side voltage supply rail and load 180. Moreover, in some embodiments, different instances of hybrid switch system 100 including hybrid switch 110 and may respectively implement the high-side switch and the low-side switch coupled to the load. For example, in a power conversion system using a half-bridge topology to drive a magnetic element, a first instance of hybrid switch system 100 may be utilized for the high-side switch of the half-bridge, and a second instance of hybrid switch system 100 may be utilized for the low-side switch of the half-bridge.

Hybrid switch 110 may include MOSFET gate input 101, IGBT gate input 103, MOSFET 111, and IGBT 113. In some embodiments, MOSFET 111 may be a silicon-carbide (“SiC”) MOSFET formed on a silicon-carbide substrate. MOSFET 111 may also be implemented in other semiconductor technologies, including wide-bandgap semiconductor technologies such as Gallium-Arsenide (“GaN”). In some embodiments, IGBT may be a silicon IGBT formed on a silicon substrate. IGBT may also be implemented in other semiconductor technologies, such as SiC. The conduction path of MOSFET 111 may be coupled in parallel to the conduction path of IGBT 113. For example, MOSFET 111 may have a gate coupled to MOSFET gate input 101, a drain coupled to first conduction terminal 116, and a source coupled to second conduction terminal 117. IGBT may have a gate coupled to IGBT gate input 103, a collector coupled to first conduction terminal 116, and an emitter coupled to second conduction terminal 117.

Hybrid switch 110 may also include diode 112 and diode 114. The respective anodes of diode 112 and diode 114 may be coupled to second conduction terminal 117, and the respective cathodes of diode 112 and diode 114 may be coupled to first conduction terminal 116. In some embodiments, diode 112 may be implemented by the internal body diode of MOSFET 111. Diode 114 may be implemented separately from diode 112, including in embodiments where diode 112 is the internal body diode of MOSFET 111. Thus, when hybrid switch 110 incurs reverse currents, diode 114 may protect MOSFET 111 from the entirety of the reverse current conducting through diode 112.

Control circuit 120 may include input terminal 121, delay generator 130, hybrid drive circuit 140, MOSFET drive output 151, and IGBT drive output 153. Control circuit 120 may be implemented in any suitable fashion according to the operation described in the present disclosure. Control circuit 120 may be configured to receive a PWM signal at input terminal 121. The PWM signal may command the control circuit 120 to turn hybrid switch 110 on and off. For example, the rising edge of the PWM signal may serve as a switch-on command, and the falling edge of the PWM signal may serve as a switch-off command, or vice versa. Control circuit 120 may repeatedly turn hybrid switch 110 on and off at a pulse width and frequency according to the pulse width and frequency of the PWM signal. Although the example embodiments described herein refer to a PWM signal, the signal received at input terminal 121, as well as the downstream control signals generated by control circuit 120, may take any suitable form for repeatedly turning on and off hybrid switch 110. For example, control circuit 120 may receive at input terminal 121 a pulse-frequency modulation (“PFM”) signal, or a clock signal with a fixed or varied on-time and frequency.

Based on the PWM signal or other command signal received at input terminal 121, control circuit 120 may provide a first drive signal DRIVE_{MOS} at MOSFET drive output 151 for driving MOSFET 111, and may provide a second drive signal DRIVE_{IGBT} at IGBT drive output 153 for driving IGBT 113. As explained in detail below, the timing of the DRIVE_{MOS} and DRIVE_{IGBT} signals may be controlled to minimize switching losses incurred when switching hybrid switch 110 from an on-state to an off-state.

In some embodiments, the components of hybrid switch system 100 may be implemented on multiple semiconductor die and co-packaged in a single multi-chip integrated circuit package. For example, in some embodiments, control circuit 120, MOSFET 111, and IGBT 113 may each be implemented on separate semiconductor die and co-packaged together in a multi-chip integrated circuit package. In other embodiments, control circuit 120 may be implemented on the same semiconductor die as one of MOSFET 111 or IGBT 113 and co-packaged with the other of MOSFET 111 or IGBT 113 in a multi-chip integrated circuit package. In other example embodiments, control circuit 120, MOSFET 111, and IGBT 113 may be implemented in separate integrated circuit packages.

As shown in FIG. 1, control circuit 120 may include delay generator 130. Delay generator 130 may be implemented in any suitable fashion according to the operation described in the present disclosure. Delay generator 130 may include delay circuit 131, delay circuit 132, and a logic gate 133.

Delay circuit 131 and delay circuit 132 may be configured to receive a PWM signal from input terminal 121. As described above, in some embodiments, the rising edge of the PWM received at input terminal 121 may serve as a switch-on command, while the falling edge of the PWM signal may serve as a switch-off command. Delay circuit 131 and delay circuit 132 may apply a first delay and a second delay respectively to a switch-off command received at input terminal 121. For example, delay circuit 131 may apply a first delay to the falling edge of the PWM signal, and generate an IGBT control signal, PWM-IGBT, for controlling IGBT 113. The first delay may be, for example, 5 ns, 10 ns, 15 ns, 30 ns, or more. Delay circuit 132 may apply a second delay to the falling edge of the PWM signal, and generate a MOSFET control signal, PWM-MOS, for controlling MOSFET 111. In some embodiments, the second delay generated by delay circuit 132 may be greater than the first delay generated by delay circuit 131. For example, the second delay generated by delay circuit 132 may be 20 ns, 30 ns, 40 ns, 50 ns, or more, greater than the first delay generated by delay circuit 131.

Logic gate 133 may include a first input coupled to receive the PWM signal from input terminal 121, and a second input coupled to receive the MOSFET control signal, PWM-MOS, from delay circuit 132. As shown in FIG. 1, logic gate 133 may be implemented as a logical-AND gate with an inversion at the first input for receiving the PWM signal. Logic gate 133 may generate a SELECT signal and may provide the SELECT signal to hybrid drive circuit 140. As described in further detail below, the MOSFET drive circuit 141 within hybrid drive circuit 140 may receive the SELECT signal at a select terminal and may be configured to select one of two voltages at which to drive the gate of MOSFET 111 during an on-state of MOSFET 111 and when switching hybrid switch 110 from an on-state to an off-state.

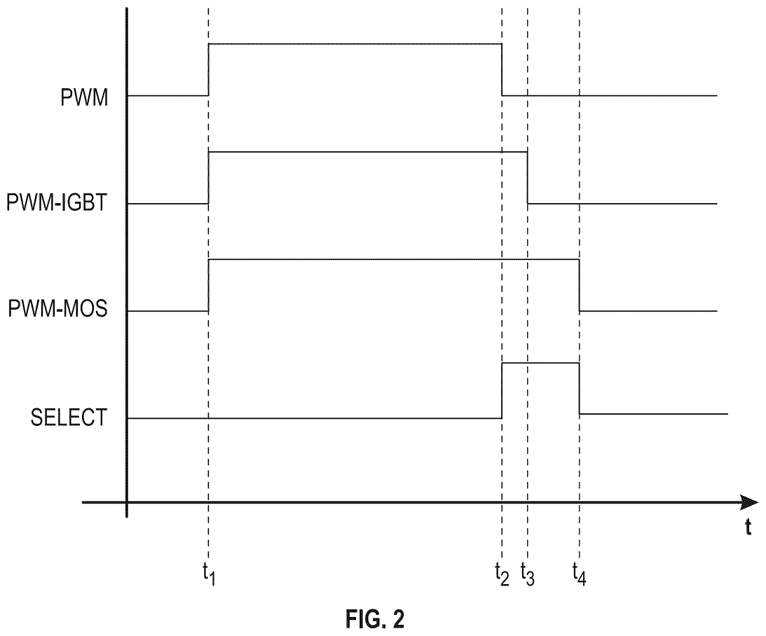

FIG. 2 illustrates a timing diagram of waveforms received and generated by delay generator 130 in accordance with embodiments of the present disclosure. FIG. 2 illustrates the timing of the PWM-IGBT, PWM-MOS, and SELECT signals described above with reference to FIG. 1 in response to the PWM signal received at input terminal 121 of control circuit 120. A falling edge and/or a continued logic-low level of PWM signal may represent a command to drive hybrid switch 110 in an off-state where the hybrid switch is non-conductive, notwithstanding minor leakage currents or reverse currents. A rising edge and/or a continued logic-high level for PWM signal may represent a command to drive hybrid switch 110 in a conductive on-state where hybrid switch 110 may conduct current from first conductive terminal 116 to second conductive terminal 117. Thus, the transition of the PWM signal from logic-low to logic-high may be a command to turn hybrid switch 110 from an off-state to an on-state. And the transition of the PWM signal from logic-high to logic-low may be a command to turn hybrid switch 110 from an on-state to and off-state. In some embodiments, the logic-low level, may be 0 V, and the logic-high level may be 1.5 V, 1.8 V, 3.3 V, 5.0 V, or any other voltage level suitable to serve as a logic-high level for low-voltage control circuitry.

At time t1, the PWM signal received at input terminal 121 may rise from a logic-low level to a logic-high level. In response to the rising edge of PWM signal at time t1, the IGBT control signal PWM-IGBT and MOSFET control signal PWM-MOS may likewise rise from a logic-low level to a logic-high level.

At time t2, the PWM signal may fall from a logic-high level to a logic-low level. In response to the falling edge of the PWM signal, delay circuit 131 may apply a first delay to the falling edge of the IGBT control signal PWM-IGBT. Thus, as shown in FIG. 2, PWM-IGBT may fall from a logic-high level to a logic-low level at time t3. The time difference between the falling edge of PWM-IGBT at time t3 and the falling edge of PWM at time t2 may represent the first delay period generated by delay circuit 131.

In response to the falling edge of PWM signal, delay circuit 132 may apply a second delay to the falling edge of MOSFET control signal PWM-MOS. Thus, as shown in FIG. 2, PWM-MOS may fall from a logic-high level to a logic-low level at time t4. The time difference between the falling edge of PWM-MOS at time t4 and the falling edge of PWM at time t2 may represent the second delay period generated by delay circuit 132. The second delay period from the falling edge of PWM to the falling edge of PWM-MOS may be greater than the first delay period from the falling edge of PWM to the falling edge of PWM-IGBT.

As shown in FIG. 2, the SELECT signal may be set to a logic-high level during the second delay period from time t2 to time t4. As described above, this second delay period represents the time between the falling edge of the PWM signal and the falling edge of PWM-MOS. As described in further detail below, the MOSFET drive circuit 141 within hybrid drive circuit 140 may receive the SELECT signal at a select terminal and utilize the SELECT signal to select one of two voltages at which to drive the gate of MOSFET 111 during an on-state of the MOSFET 111 and during the transition of hybrid switch 110 from an on-state to an off-state.

Hybrid drive circuit 140 may be implemented in any suitable fashion according to the operation described in the present disclosure. Referring back to FIG. 1, hybrid drive circuit 140 may include MOSFET drive circuit 141 and IGBT drive circuit 143.

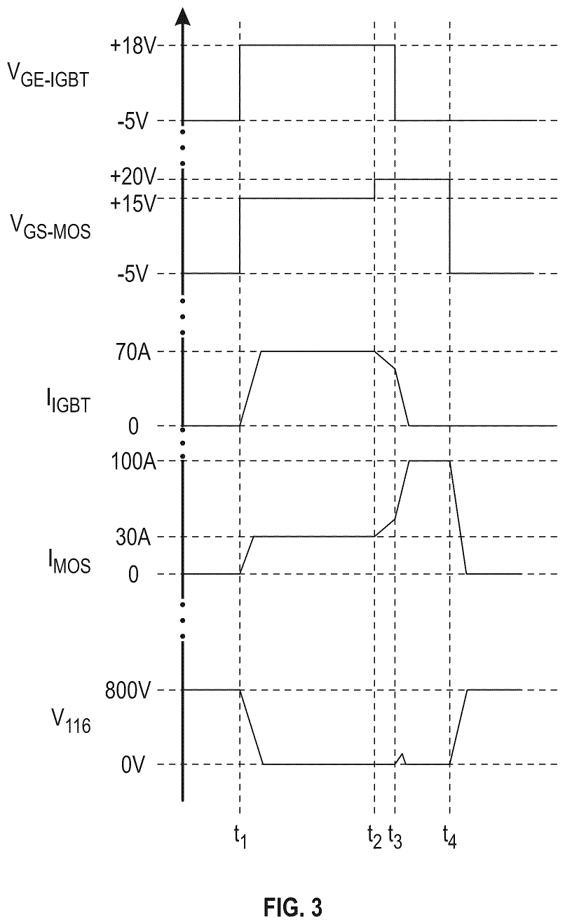

MOSFET drive circuit 141 may be configured to receive PWM-MOS and to generate an output signal DRIVE_{MOS} for driving MOSFET 111. For example, MOSFET drive circuit 141 may include a level shifter that may level shift the logic-low or logic-high level of PWM-MOS to generate an output signal DRIVE_{MOS} with voltages sufficient to turn MOSFET 111 on and off at desired levels. In response to a logic-low level on PWM-MOS, MOSFET drive circuit 141 may apply, for example, a gate-to-source voltage of −5 V to drive MOSFET 111 in an off-state. And in response to a logic-high level on PWM-MOS, MOSFET drive circuit 141 may apply, for example, one of two potential positive gate-to-source voltages to MOSFET 111 to drive MOSFET 111 in an on-state. For example, during the on-state of MOSFET 111, MOSFET drive circuit 141 may select one of two voltages at which to drive MOSFET 111 based on the SELECT signal received at the select terminal. As described in further detail below with reference to FIG. 3, MOSFET drive circuit 141 may be configured to select a first gate-to-source voltage, at for example, a first voltage level of +15 V, during the on-time of hybrid switch 110. MOSFET drive circuit 141 may also be configured to select a second gate-to-source voltage, at for example, a second voltage level of +20 V, during the second delay period from the falling edge of the PWM signal at time t2 to the falling edge of PWM-MOS at time t4.

IGBT drive circuit 143 may be configured to receive PWM-IGBT and to generate an output signal DRIVE_{IGBT} for driving IGBT 113. For example, IGBT drive circuit 143 may include a voltage level shifter that may level shift the logic-low or logic-high level of PWM-IGBT to generate an output signal DRIVE_{IGBT} with voltages sufficient to turn IGBT 113 on and off at desired levels. In response to a logic-low level on PWM-IGBT, IGBT drive circuit 143 may apply, for example, a gate-to-emitter voltage of −5 V to IGBT 113 to drive IGBT 113 in an off-state. And in response to a logic-high level on PWM-IGBT, IGBT drive circuit 143 may apply, for example, a gate-to-emitter voltage at, for example, a third voltage level of +18 V to IGBT 113 to drive IGBT 113 in an on-state. As described in further detail below, the third voltage level of, for example +18 V, with which IGBT 113 may be driven during the on-time of hybrid switch 110 may be greater than the first voltage level of, for example +15 V, with which MOSFET 111 may be driven during the on-time of hybrid switch 110.

FIG. 3 illustrates a timing diagram of waveforms for controlling hybrid switch 110 in accordance with embodiments of the present disclosure. Times t1, t2, t3, and t4 are illustrated in FIG. 3 to align with the corresponding times t1, t2, t3, and t4 in FIG. 2.

Prior to time t1, hybrid switch 110 may be driven in an off-state, with the gate-to-emitter voltage V_{GE_IGBT} of IGBT 113 at −5 V for example, and the gate-to-source voltage V_{GS_MOS} of MOSFET 111 at −5 V for example. At time t1, control circuit 120 may receive a drive command to turn on hybrid switch 110. Thus, at time t1, hybrid switch 110 may transition to an on-state, with the gate-to-emitter voltage V_{GE_IGBT} of IGBT 113 at +18V for example, and the gate-to-source voltage V_{GS_MOS} of MOSFET 111 at +15 V for example.

As shown in FIG. 3, the current I_{IGBT} through IGBT 113 and the current I_{MOS} through MOSFET 111 may increase in response to IGBT 113 and MOSFET 111 being driven in an on-state. In some embodiments, IGBT 113 and MOSFET 111 may be configured such that the majority of the load current I_{LOAD} conducts through IGBT 113 during the on-state of hybrid switch 110. For example, in some embodiments, IGBT 113 and MOSFET 111 may be configured such that 70-80% of the load current I_{LOAD} is conducted through IGBT 113, and the remaining 20-30% of the load current I_{LOAD} is conducted through MOSFET 111 during the on-state of hybrid switch 110. To provide such a distribution of current, the die area of IGBT 113 may be larger than the die area of MOSFET 111. The distribution of current between IGBT 113 and MOSFET 111 may also be controlled by the respective voltages used to drive the gates of IGBT 113 and MOSFET 111. In some embodiments, IGBT 113 may be driven with a gate-to-emitter voltage greater than the gate-to-source voltage of MOSFET 111 during the on-time of hybrid switch 110 between time t1 and time t2. For example, as shown in FIG. 3 during the on-time between time t1 and time t2, IGBT 113 may be driven with a gate-to-emitter voltage level of +18 V and MOSFET 111 may be driven with a gate-to-source voltage level of +15 V.

Between times t2 and t4, hybrid switch 110 may transition from an on-state to an off-state. The transition scheme disclosed herein may deploy multiple techniques to reduce the switching loss associated with switching hybrid switch 110 from an on-state to an off-state. For example, the switching loss associated with turning off IGBT 113 may be reduced by keeping MOSFET 111 on, and thereby holding the voltage at the collector of IGBT 113 low, during the transition of IGBT 113 from an on-state to an off-state. Thus, by keeping MOSFET 111 in an on-state during the transition of IGBT 113 to an off-state, the switching loss associated with turning off IGBT 113 may be reduced.

The transition of the load current I_{LOAD} from IGBT 113 to MOSFET 111 may be referred to as commutation. However, when MOSFET 111 is driven at its nominal on-state gate-to-source voltage, for example +15 V, the rate (dI_{MOS}/dt) at which I_{MOS} is able to increase may be less than the rate (dI_{IGBT}/dt) at which I_{IGBT} decreases. Thus, as shown at time t3 in FIG. 3, the voltage V₁₁₆ at the first conduction terminal 116 to which the drain of MOSFET 111 and the collector of IGBT 113 are coupled may spike. The increased voltage at the collector of IGBT 113 may thus result in switching loss associated with turning IGBT 113 off. However, as explained below, control circuit 120 may drive the gate of MOSFET 111 during the transition of hybrid switch 110 from an on-state to an off-state in a manner that reduces this voltage spike, and thus reduces the associated switching loss.

Driving the gate of MOSFET 111 with an increased voltage during the transition of IGBT 113 from an on-state to an off-state may further reduce the switching loss associated with turning off IGBT 113. As described above with reference to FIG. 1, load 180 may be an inductive element such as an inductor or a winding of a transformer. Commutation mismatch between IGBT 113 and MOSFET 111 tries to change load current I_{LOAD}. However, due to the inductive load, the load current I_{LOAD} may not change instantly when IGBT is turned off. To keep the current constant in an inductive load, the voltage across the load must increase, resulting in a voltage potential change.

To improve the commutation of current from IGBT 113 to MOSFET 111 when IGBT 113 is turned off, control circuit 120 may first increase the gate-to-source voltage applied to MOSFET 111. The increased gate-to-source voltage applied to MOSFET 111 may increase the rate (dI_{MOS}/dt) at which the current I_{MOS} through MOSFET 111 is able to increase when IGBT 113 is turned off. Thus, the voltage spike at time t3, and the associated switching loss incurred by turning off IGBT 113, may be reduced.

Referring back to FIG. 1 and FIG. 2, at time t2, control circuit 120 may receive a command to switch off hybrid switch 110 in the form of the falling edge of the PWM signal. In response to the switch-off command at time t2, control circuit 120 may increase the gate-to-source voltage applied to MOSFET 111 from a first voltage level to a second voltage level. As shown in FIG. 3, the gate-to-source voltage V_{GS_MOS} of MOSFET 111 may be increased from a first voltage level of +15 V for example to a second voltage level of +20 V for example. After a first delay, as measured from time t2 to time t3, the gate-to-emitter voltage V_{GE_IGBT} of IGBT 113 may be driven low to turn off IGBT 113. With the higher gate-to-source voltage applied to MOSFET 111 during the transition of IGBT 113 from an on-state to an off-state, the commutation of current from IGBT 113 to MOSFET 111 beginning at time t3 may be improved. Thus, the voltage spike at the collector of IGBT 113, and the switching loss associated with turning off IGBT 113, may be reduced. Subsequently, after a second delay, as measured from time t2 to time t4, the gate-to-source voltage V_{GS_MOS} of MOSFET 111 may be driven low to turn off MOSFET 111. When MOSFET 111 reaches the off-state, the process for transitioning hybrid switch 110 as a whole from an on-state to an off-state may be complete.

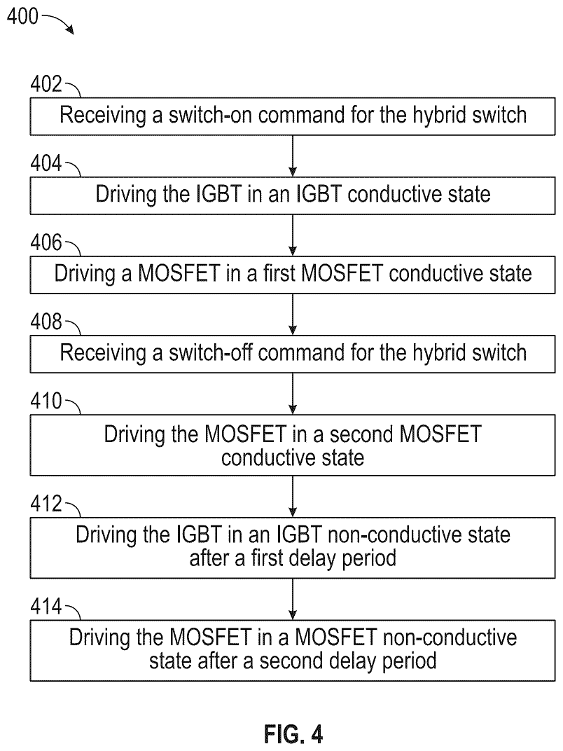

FIG. 4 illustrates operation of an example method 400 for controlling a hybrid switch in accordance with embodiments of the present disclosure. Method 400 may be performed by any suitable mechanism, such as control circuit 120. Method 400 may be performed with fewer or more steps than shown in FIG. 4. Moreover, steps of method 400 may be omitted, repeated, performed in parallel, performed in a different order than shown in FIG. 4, or performed recursively. Unless otherwise specified, one or more steps of method 400, although shown in an order, may be performed at the same time or in a re-ordered manner.

At step 402, a switch-on command for the hybrid switch may be received. For example, as described above with reference to FIG. 1 and FIG. 2, control circuit 120 may receive a switch-on command in the form of a rising edge of a PWM signal received at input terminal 121.

At step 404, an IGBT of the hybrid switch may be driven in an IGBT conductive state in response to the switch-on command. For example, hybrid switch 110 may include IGBT 113. In response to the switch-on command, control circuit 120 may drive IGBT 113 in a conductive state by driving IGBT 113 with a gate-to-emitter voltage V_{GE_IGBT} at, for example, the third voltage level of +18 V. IGBT 113 may thus conduct a current I_{IGBT} from its collector to its emitter. For the purposes of the present disclosure, a conductive or non-conductive state of IGBT 113 may be referred to as an IGBT conductive state or an IGBT non-conductive state to differentiate from those of MOSFET 111.

At step 406, a MOSFET of the hybrid switch may be driven in a first MOSFET conductive state in response to the switch-on command. For example, hybrid switch may include MOSFET 111. In response to the switch-on command, control circuit 120 may drive MOSFET 111 in a first conductive state by driving MOSFET 111 with a gate-to-source voltage V_{GS_MOS} at, for example, a first voltage level of +15 V. MOSFET 111 may thus conduct a current I_{MOS} from its drain to its source. For the purposes of the present disclosure, the conductive and non-conductive states of MOSFET 111 may be referred to as MOSFET conductive states or a MOSFET non-conductive state to differentiate from those of IGBT 113.

At step 408, a switch-off command for the hybrid switch may be received. For example, as described above with reference to FIG. 1 and FIG. 2, control circuit 120 may receive a switch-off command in the form of a falling edge of a PWM signal received at input terminal 121.

At step 410, the MOSFET of the hybrid switch may be driven in a second MOSFET conductive state in response to the switch-off command. For example, in response to the switch-off command, control circuit 120 may drive MOSFET 111 in a second conductive state by driving MOSFET 111 with a gate-to-source voltage V_{GS_MOS} at, for example, a second voltage level of +20 V. As shown in FIG. 3, control circuit 120 may drive MOSFET 111 in the second conductive state by driving MOSFET 111 with a gate-to-source voltage V_{GS_MOS} of, for example, +20 V, from time t2 to time t4. MOSFET 111 may be more conductive when driven in the second conductive state with a gate-to-source voltage V_{GS_MOS} of, for example, +20 V, than when driven in the first conductive state with a gate-to-source voltage V_{GS_MOS} of, for example, +15 V.

As described above with reference to FIG. 1 and FIG. 2, the falling edge of the PWM signal at time t2 may represent a switch-off command. In response to the switch-off command, delay generator 130 of control circuit 120 may generate a first signal, PWM-IGBT, with a first delay, and may generate a second signal, PWM-MOS, with a second delay. Delay generator 130 may also generate a SELECT signal based on the second signal, PWM-MOS, and the PWM signal. For example, as shown in FIG. 2, the SELECT signal may transition from a logic-low level to a logic-high level at time t2 in response to the switch-off command. Referring back to FIG. 1, MOSFET drive circuit 141 may select between conductive states based on the PWM-MOS signal and the SELECT signal. For example, when the second signal, PWM-MOS, is in a logic-high state, MOSFET drive circuit 141 may select between the first MOSFET conductive state with a gate-to-source voltage V_{GS_MOS} of +15 V, and the second MOSFET conductive state with a gate-to-source voltage V_{GS_MOS} of +20 V, based on the SELECT signal. For example, the SELECT signal may transition from a logic-low level to a logic-high level in response to the switch-off command at time t2, and MOSFET drive circuit may in turn select the second conductive state with a with a gate-to-source voltage V_{GS_MOS} of +20 V. Thus, MOSFET drive circuit 141 may select between the first MOSFET conductive state and the second MOSFET conductive state based at least in part on the switch-off command at the falling edge of the PWM signal and the second signal, PWM-MOS.

At step 412, the IGBT may be driven in an IGBT non-conductive state after a first delay period that begins in response to the switch-off command. For example, in response to the falling edge of a PWM signal received at input terminal 121, delay circuit 131 may generate an IGBT control signal PWM-IGBT with a first delay relative to the falling edge of the PWM signal. At the expiration of a first delay period beginning at the falling edge of the PWM signal, PWM-IGBT may transition from a logic-high state to a logic-low state, thereby instructing IGBT drive circuit 143 to apply, for example, a gate-to-emitter voltage of −5 V to IGBT 113 to drive IGBT 113 in a non-conductive off-state. As shown in FIG. 2, the first delay period may begin at time t2 with the falling edge of the PWM signal and expire at time t3 with the falling edge of PWM-IGBT. And as shown in FIG. 2 and FIG. 3, the first delay period may expire at time t3, at which time IGBT drive circuit 143 may apply, for example, a gate-to-emitter voltage of −5 V to IGBT 113 to drive IGBT 113 in a non-conductive off-state.

At step 414, the MOSFET may be driven in a non-conductive state after a second delay period, the second delay period beginning in response to the switch-off command and lasting longer than the first delay period. For example, in response to the falling edge of a PWM signal received at input terminal 121, delay circuit 132 may generate a MOSFET control signal PWM-MOS with a second delay relative to the falling edge of the PWM signal. At the expiration of a second delay period beginning at the falling edge of the PWM signal, PWM-MOS may transition from a logic-high state to a logic-low state, thereby instructing MOSFET drive circuit 141 to apply, for example, a gate-to-source voltage of −5 V to MOSFET 111 to drive MOSFET 111 in a non-conductive off-state. As shown in FIG. 2, the second delay period may begin at time t2 with the falling edge of the PWM signal and expire at time t4 with the falling edge of the PWM-MOS signal. The second delay period from the falling edge of PWM to the falling edge of PWM-MOS may thus be greater than the first delay period from the falling edge of PWM to the falling edge of PWM-IGBT. And as shown in FIG. 2 and FIG. 3, the second delay period may expire at time t4, at which time MOSFET drive circuit 141 may apply, for example, a gate-to-source voltage of −5 V to MOSFET 111 to drive MOSFET 111 in a non-conductive off-state.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

What is claimed is:

1. A switch system, comprising:
a hybrid switch comprising:
an insulated-gate bipolar transistor (IGBT); and
a metal-oxide semiconductor field effect transistor (MOSFET); and
a control circuit comprising:
an input terminal configured to receive a switch-off command;
an IGBT drive circuit configured to switch off the IGBT in response to expiration of a first delay period that begins in response to the switch-off command; and
a MOSFET drive circuit configured to:
increase a gate-to-source voltage of the MOSFET from a first voltage level to a second voltage level in response to the switch-off command;
drive the MOSFET at the second voltage level for a second delay period that begins in response to the switch-off command and that is longer than the first delay period; and
switch the MOSFET off in response to the expiration of the second delay period.

2. The switch system of claim 1, wherein the MOSFET comprises a silicon-carbide MOSFET.

3. The switch system of claim 1, wherein the IGBT comprises a silicon IGBT.

4. The switch system of claim 1, wherein the IGBT has a larger die area than the MOSFET.

5. The switch system of claim 1, wherein:
the input terminal is further configured to receive a switch-on command;
the MOSFET drive circuit is further configured to drive the gate-to-source voltage of the MOSFET at the first voltage level in response to the switch-on command; and
the IGBT drive circuit is further configured to, in response to the switch-on command, drive a gate-to-emitter voltage of the IGBT at a third voltage level that is greater than the first voltage level of the gate-to-source voltage of the MOSFET.

6. The switch system of claim 1, wherein the control circuit further comprises:
a first delay circuit configured to generate a first signal with a first delay corresponding to the first delay period in response to the switch-off command; and
a second delay circuit configured to generate a second signal with a second delay corresponding to the second delay period in response to the switch-off command.

7. The switch system of claim 1, wherein the IGBT, the MOSFET, and the control circuit are co-packaged in a multi-chip integrated circuit package.

8. The switch system of claim 1, wherein the MOSFET drive circuit further comprises a select terminal and is configured to select one of two voltages at which to drive a gate of the MOSFET during an on-state of the MOSFET based on a select signal received at the select terminal during the on-state of the MOSFET.

9. A hybrid switch system, comprising:
a hybrid switch comprising:
an insulated-gate bipolar transistor (IGBT); and
a metal-oxide semiconductor field effect transistor (MOSFET); and
a control circuit comprising:
an input terminal configured to receive a switch-off command;
a delay generator configured to, in response to the switch-off command, generate an IGBT control signal having a first delay, and to generate a MOSFET control signal having a second delay;
an IGBT drive circuit configured to switch off the IGBT in response to the IGBT control signal having the first delay; and
a MOSFET drive circuit configured to increase a gate-to-source voltage applied to the MOSFET in response to the switch-off command and to subsequently switch off the MOSFET in response to the MOSFET control signal having the second delay.

10. The hybrid switch system of claim 9, wherein the MOSFET comprises a silicon-carbide MOSFET.

11. The hybrid switch system of claim 9, wherein the IGBT comprises a silicon IGBT.

12. The hybrid switch system of claim 9, wherein the IGBT has a larger die area than the MOSFET.

13. The hybrid switch system of claim 9, wherein:
the input terminal is further configured to receive a switch-on command;
the MOSFET drive circuit is further configured to drive the gate-to-source voltage of the MOSFET at a first voltage level in response to the switch-on command and at a second voltage level higher than the first voltage level in response to the switch-off command; and
the IGBT drive circuit is further configured to drive a gate-to-emitter voltage of the IGBT at a third voltage level in response to the switch-on command that is greater than the first voltage level of the gate-to-source voltage of the MOSFET.

14. The hybrid switch system of claim 9, wherein the MOSFET drive circuit further comprises a select terminal and is configured to select one of two voltages at which to drive a gate of the MOSFET during an on-state of the MOSFET based on a select signal received at the select terminal during the on-state of the MOSFET.

15. A method for controlling a hybrid switch, comprising:
receiving a switch-on command for the hybrid switch;
driving an insulated-gate bipolar transistor (IGBT) of the hybrid switch in an IGBT conductive state in response to the switch-on command;
driving a metal-oxide semiconductor field effect transistor (MOSFET) of the hybrid switch in a first MOSFET conductive state in response to the switch-on command;
receiving a switch-off command for the hybrid switch;
driving the MOSFET in a second MOSFET conductive state in response to the switch-off command, wherein the MOSFET is more conductive in the second MOSFET conductive state than in the first MOSFET conductive state;
driving the IGBT in an IGBT non-conductive state after a first delay period, the first delay period beginning in response to the switch-off command; and
driving the MOSFET in a MOSFET non-conductive state after a second delay period, the second delay period beginning in response to the switch-off command and lasting longer than the first delay period.

16. The method for controlling a hybrid switch of claim 15, wherein:
driving the MOSFET in the first MOSFET conductive state comprises applying a first gate-to-source voltage to the MOSFET; and
driving the MOSFET in the second MOSFET conductive state comprises applying a second gate-to-source voltage to the MOSFET greater than the first gate-to-source voltage.

17. The method for controlling a hybrid switch of claim 15, wherein:
driving the MOSFET in the first MOSFET conductive state comprises applying a first gate-to-source voltage to the MOSFET; and
driving the IGBT in the IGBT conductive state comprises applying a first gate-to-emitter voltage to the IGBT greater than the first gate-to-source voltage applied to the MOSFET.

18. The method for controlling a hybrid switch of claim 15, wherein the IGBT is more conductive in the IGBT conductive state than the MOSFET in the first MOSFET conductive state.

19. The method for controlling a hybrid switch of claim 15, further comprising:
generating a first signal with a first delay corresponding to the first delay period in response to the switch-off command; and
generating a second signal with a second delay corresponding to the second delay period in response to the switch-off command.

20. The method for controlling a hybrid switch of claim 19, further comprising selecting between the first MOSFET conductive state and the second MOSFET conductive state based at least in part on the switch-off command and the second signal.
